(19) United States
(12) Patent Application Publication
(10) Pub. No.: US 2011/0034339 A1
(43) Pub. Date: Feb. 10, 2011

(54) VERTICALLY-ALIGNED NANOPILLAR ARRAY ON FLEXIBLE, BIAXIALLY-TEXTURED SUBSTRATES FOR NANOELECTRONICS AND ENERGY CONVERSION APPLICATIONS

(76) Inventor: AMIT GOYAL, Knoxville, TN (US)

Correspondence Address: NOVAK DRUCE +QUIGG LLP/UTB, CITY PLACE TOWER, 525 OKEECHOBEE BLVD., 15TH FLR, WEST PALM BEACH, FL, 33401, US

(21) Appl. No.: 12/849,970

(22) Filed: Aug. 4, 2010

Related U.S. Application Data
(63) Continuation-in-part of application No. 12/711,309, filed on Feb. 24, 2010.
(60) Provisional application No. 61/231,501, filed on Aug. 5, 2009.
(60) Provisional application No. 61/231,063, filed on Aug. 4, 2009.

(51) Int. Cl. B32B 3/10; H01L 39/02; B32B 5/02; C30B 1/00

(52) U.S. Cl. 505/237; 428/114; 428/119; 117/87; 977/742; 977/762

(57) ABSTRACT

An article having a biaxially textured substrate surface and a plurality of vertically-aligned, epitaxial nanopillars supported on the surface substrate is disclosed. The article can include a matrix phase deposited on the biaxially textured surface and between the plurality of vertically-aligned, epitaxial nanopillars. The nanopillars can include a coating. The matrix phase and the vertically-aligned, epitaxial nanopillars can form an electronically active layer selected from the group consisting of a superconducting material, a ferroelectric material, a multiferroic material, a magnetic material, a photovoltaic material, a electrical storage material, and a semiconductor material. A method of making the article is also disclosed.

### CROSS-REFERENCE TO RELATED APPLICATIONS

This application claims priority to U.S. Provisional Application No. 61/231,501, entitled “Vertically-Aligned, Epitaxial Nanorod Array on Flexible, Single-Crystal, or Single-Crystal-Like Substrates for Nanoelectronics and Energy Conservation Applications,” filed Aug. 5, 2009, and is a continuation-in-part of U.S. application Ser. No. 12/711,309, entitled “Structures with Three Dimensional Nanofences Comprising Single Crystal Segments,” filed Feb. 24, 2010, which claims priority to U.S. Provisional Application No. 61/231,063, filed Aug. 4, 2009, the entireties of which are incorporated herein by reference.

### STATEMENT REGARDING FEDERALLY SPONSORED RESEARCH OR DEVELOPMENT

The United States Government has rights in this invention pursuant to contract no. DE-AC05-00OR22725 between the United States Department of Energy and UT-Battelle, LLC.

### FIELD OF THE INVENTION

This disclosure relates to the electrical components, and more particularly to electrical components including a biaxially textured surface and a plurality of vertically-aligned nanopillars deposited thereon.

### BACKGROUND OF THE INVENTION

While fabrication of a variety of interesting nanostructures has been demonstrated in small samples, the methods for making such nanostructures are not readily scalable or consistently reproducible. For example, in some instances, deposits in a furnace downstream trap have to be scraped and nanostructures harvested from the scrapings. Therefore, such nanostructures are prohibitively expensive and the utility thereof cannot be realized. Reproducible and controlled fabrication of nanostructures is needed for many novel electronic and electromagnetic devices, such as those involving semiconductors and superconductors.

### SUMMARY OF THE INVENTION

An article that includes a substrate having a biaxially textured surface, and a plurality of vertically-aligned, epitaxial nanopillars supported by the biaxially textured surface substrate is disclosed. A matrix phase can be deposited on the biaxially textured surface between the plurality of vertically-aligned, epitaxial nanopillars. A coating can be deposited on the plurality of vertically-aligned, epitaxial nanopillars. The matrix phase can be an epitaxial layer. The plurality of vertically-aligned, epitaxial nanopillars can be nanorods, nanotubes, and combinations thereof.

The matrix phase and the plurality of vertically-aligned, epitaxial nanopillars can be part of an electronically active layer. The electronically active layer can be a superconducting material, a ferroelectric material, a multiferroic material, a magnetic material, a photovoltaic material, a electrical storage material, and a semiconductor material.

The diameter of the vertically-aligned, epitaxial nanopillars can range from 5-100 nm. The vertically-aligned, epitaxial nanopillars can include at least two epitaxial sub-pillars having different compositions along a length of each of the vertically-aligned, epitaxial nanopillars.

Also disclosed is a method of fabricating a device having a plurality of vertically-aligned, epitaxial nanopillars. The method can include:

a. providing a substrate having a biaxially textured surface;

b. forming a template on the biaxially textured surface, where the template defines a nanocatalyst pattern; and

c. growing an epitaxial layer on the biaxially textured surface, where the epitaxial layer includes a plurality of vertically-aligned, epitaxial nanopillars deposited in the nanocatalyst pattern.

The method can also include removing the template to expose the plurality of vertically-aligned, epitaxial nanopillars and the biaxially textured surface between the plurality of vertically-aligned, epitaxial nanopillars. Following the removal step, the method can also include depositing a matrix phase on the biaxially textured substrate and between the plurality of vertically-aligned, epitaxial nanopillars. Alternately, following the removal step, the method can include depositing an epitaxial coating on the plurality of vertically-aligned, epitaxial nanopillars; and the depositing the matrix phase on the biaxially textured substrate and between the plurality of coated vertically-aligned, epitaxial nanopillars.

The forming step of the method can also include depositing an anodization catalyst layer supported on the biaxially textured surface; depositing a template precursor layer comprising a metal supported on the anodization catalyst layer; and anodizing the metal template precursor layer to form the template. The nanocatalyst pattern can include pores formed during the anodizing step. The pores can extend from a bottom surface of the template to a top surface of the template.

These and other embodiments are described in more detail below,

### BRIEF DESCRIPTION OF THE DRAWINGS

A fuller understanding of the present invention and the features and benefits thereof will be obtained upon review of the following detailed description together with the accompanying drawings, in which:

FIG. 1 is a side view of an article disclosed herein, having a plurality of nanopillars deposited on a support.

FIGS. 2A and 2B are a side view and top view, respectively, of a nanorod deposited on a support.

FIGS. 3A and 3B are a side view and top view, respectively, of a nanotube deposited on a support.

FIG. 4 is a cross-sectional view of an article disclosed herein, having a plurality of nanopillars immersed in a matrix phase.

FIGS. 5A and 5B are a side view and top view, respectively, of an article disclosed herein, having an upper surface with interfaces between the nanopillars and the matrix phase.

FIGS. 6A and 6B are a cross-sectional view and top view, respectively, of support supporting a nanorod having a coating deposited thereon.

FIG. 7A-H is a sequence of side views showing the method of making a variety of articles disclosed herein with a plurality of nanotubes deposited on a support.

FIG. 8 is a side view of an article disclosed herein, having nanopillars comprising a plurality of stacked sub-pillars.

FIG. 9 is a side view of an article disclosed herein, having nanopillars comprising a plurality of stacked sub-pillars with a coating thereon and a matrix phase deposited between the nanopillars.

FIG. 10 is a side view of an article disclosed herein, having nanopillars comprising a plurality of stacked sub-pillars with sub-coatings deposited thereon and a matrix phase deposited between the nanopillars.

FIG. 11A-F is a sequence of side views showing the method of making a variety of articles disclosed herein with a plurality of nanorods deposited on a support.

FIG. 12 is a photomicrograph showing the structure of an anodized aluminum oxide (AAO) template that is useful in carrying out examples of the present invention.

FIG. 13 is an image of MgO+Ni nanorods with branches grown on a MgO single crystal substrate.

For a better understanding of the present invention, together with other and further objects, advantages and capabilities thereof, reference is made to the following disclosure and appended claims in connection with the above-described drawings.

### DETAILED DESCRIPTION OF THE INVENTION

The present invention is an article and a method of making the same, inter alia, to create in a controlled, reproducible and scalable manner, vertically-aligned, nanopillar arrays of materials. If desired, the nanopillars can then be surrounded with a matrix phase different in its properties from the nanopillars. The present invention represents a major breakthrough in nanomaterials and the first example of controlled growth of nanopillar arrays in predetermined nano-patterns of a variety of biaxially textures materials in a scalable manner.

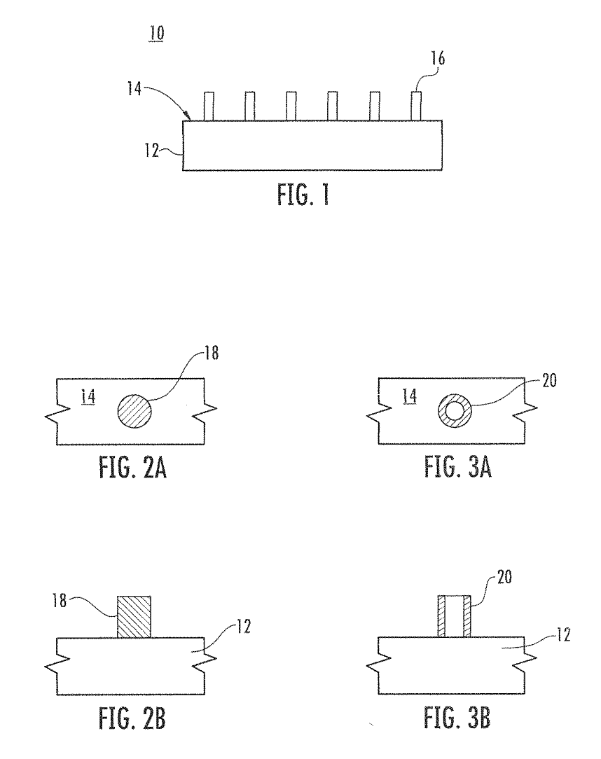

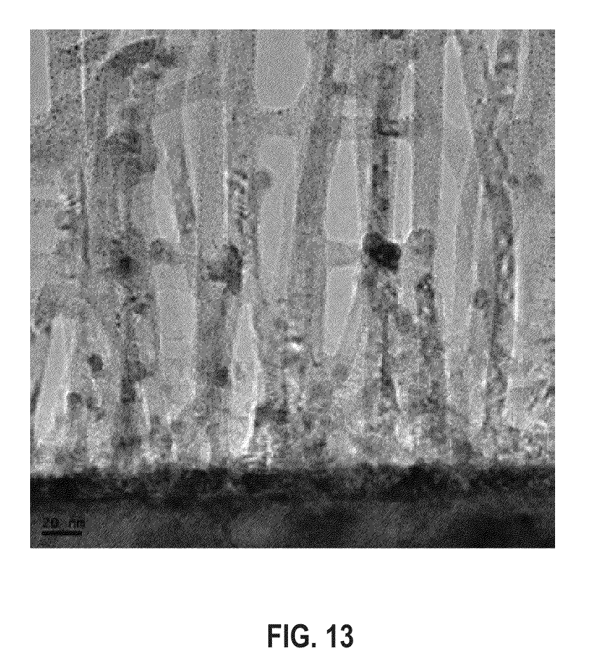

As shown in FIGS. 1-11, the article 10 disclosed herein includes a substrate 12 having a biaxially textured surface 14, and a plurality of vertically-aligned, epitaxial nanopillars 16 supported on the biaxially textured surface 14. The vertically-aligned, epitaxial nanopillars 16 can be single crystal nanopillars 16. The vertically-aligned, epitaxial nanopillars 16 in any of the embodiments described herein can be branched or unbranched. As can be seen in FIG. 13, where the nanopillars are branched, the branches can extend from a first nanopillar to a second nanopillar. As used herein, “vertically-aligned” features are aligned substantially normal to a surface, e.g., the biaxially textured surface 14, or deviate from normal by less than 15 degree, or less than 10 degrees, or less than 5 degrees, or less than 1 degree, or less than 0.1 degree.

As used herein, “biaxially textured” refers to {100} <100> crystallographic orientations both parallel and perpendicular to the basal plane of a material, including texture aligned along a first axis along the [001] crystal direction, and along a second axis having a crystal direction selected from the group consisting of [111], [101], [113], [100], and [010]. The degree of biaxial texture in the layer of which the biaxially textured surface 14, as specified by the FWHM of the out-of-plane and in-plane diffraction peak, is typically greater than 2° and less than 20°, preferably less than 15°, and optimally less than 10°.

As used herein, a first layer is “supported on” second layer if the first layer is above the second layer in a stack, whereas a first layer is “deposited on” a second layer if the first layer is above and in direct contact with the second layer. In other words, there can be intermediate layers between a first layer supported on a second layer, whereas there are no intermediate layers if the first layer is deposited on the second layer. It is intended that where the phrase “supported on” is used in the specification, the layer can be either supported on or deposited on the layer by which it is supported.

As shown in FIGS. 2-3, the plurality of nanopillars 16 can be nanorods 18, nanotubes 20, or combinations of both 18 and 20. Nanorod 18 is used to refer to solid nanopillars 16 formed of a single, uniform composition, whereas nanotube 20 is used to refer to hollow nanopillars 16, whether the nanotube 20 is filled with a core phase 30 or not. Nanopillars can have at least one dimension ranging from 1 to 500 nm, or 5 to 250 nm, or 10 to 100 nm, or any combination of these endpoints, e.g., 250 to 500 nm. Nanopillars 16 generally have at least one dimension that is less than 100 nm. An outer diameter of the vertically-aligned, epitaxial nanopillars 16 can range from 1 to 100 nm, or from 2 to 75 nm, or from 5 to 50 nm, or any combination of these endpoints, e.g., 2 to 50 nm. An inner diameter of the nanotubes 20 can range from 1-50 nm, or from 2 to 40 nm, or from 3 to 30 nm, or any combination of these endpoints, e.g., 2 to 3 nm.

The article 10 can include an electronically active layer 22 that includes a matrix phase 24 deposited on the biaxially textured surface 14 and between the plurality of vertically-aligned, epitaxial nanopillars 16. The matrix phase 24 can be continuous, while the vertically-aligned nanopillars can be spatially separated in an ordered array. The matrix phase 24 can be epitaxial or non-epitaxial depending on the particular function of the article 10 and the electronically active layer 22. The electronically active layer 22 can be a layer selected from the group that includes, but is not limited to, a superconducting layer, a ferroelectric layer, a multiferroic layer, a magnetic layer, a photovoltaic layer, an electrical storage layer (e.g., battery, capacitor, etc.), a semiconductor layer, and a combination thereof.

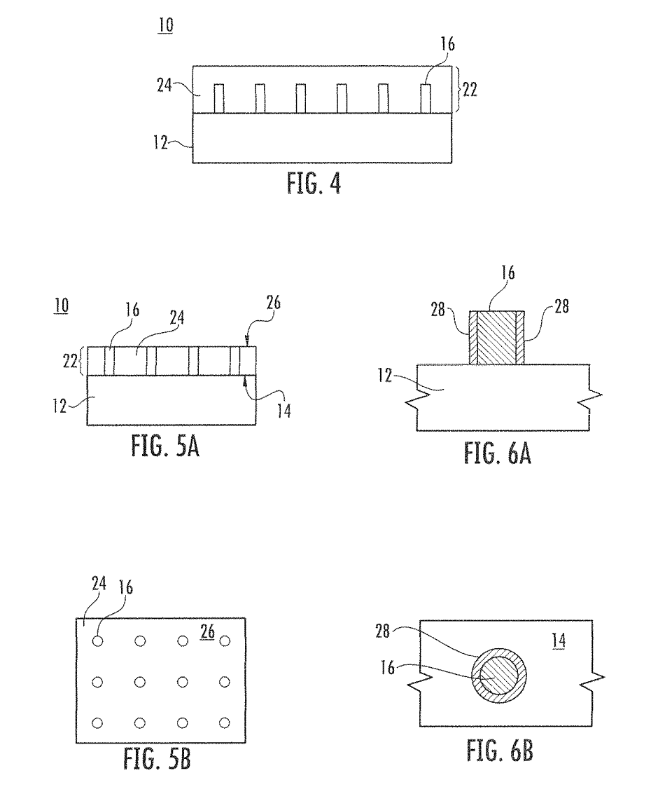

As shown in FIG. 4, the nanopillars 16 can be immersed in the matrix phase 24. Alternately, as shown in FIGS. 5A and 5B, the nanopillars 16 and the matrix phase 24 can be coextensive along an upper surface 26 of the electronically active layer 22. In other words, the upper surface 26 can include interfaces between the nanopillars 16 and the matrix phase 24.

As shown in FIGS. 6A and 6B, the vertically-aligned, epitaxial nanopillars 16 can have a coating 28 deposited thereon. The coating 28 can be an epitaxial layer deposited on the vertically-aligned, epitaxial nanopillars 16. The coating 28 can have a first composition and the matrix phase 24 can have a second composition. The first and second compositions can be the same or different. Similarly, the coating 28 can have a first crystallographic orientation and the matrix phase 24 can have a second crystallographic orientation. The first and second crystallographic orientations can be the same or different. The first crystallographic orientation can be the same as the crystallographic orientation of the nanopillars 16 and the second crystallographic orientation can be the same as that of the biaxially textured surface 14.

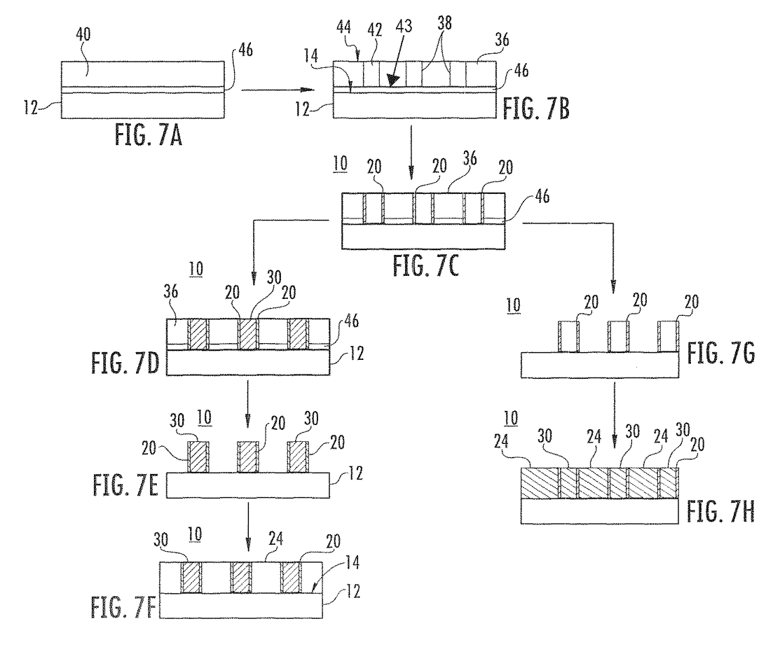

As shown in FIG. 7, the nanopillars 16 can be nanotubes 20. The nanotubes 20 can be filled with a core phase 30, as shown in FIGS. 7E, 7F and 7H. The core phase 30 can be the different from or the same as the matrix phase 24, as shown in FIGS. 7F and 7H, respectively. The core phase 30 can be epitaxial or non-epitaxial.

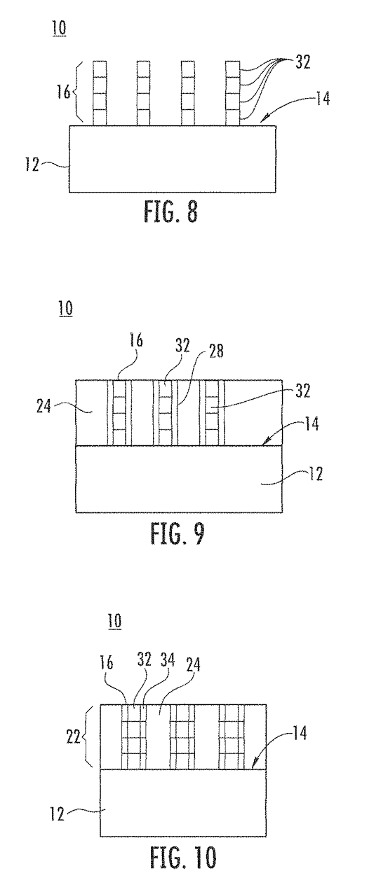

As shown in FIG. 8, the vertically-aligned, epitaxial nanopillars 16 can include at least two epitaxial sub-pillars 32 having different compositions along a length of each of the vertically-aligned, epitaxial nanopillars 16. Each of the sub-pillars 32 can have a composition and crystallographic orientation that is the same or different from the sub-pillar 32 on which it is deposited. As used herein, “sub-pillar” refers to (i) a structure that would otherwise be considered a nanopillar (ii) that also forms a part of a continuous, vertically-aligned, epitaxial nanopillar 16 but has a different composition than another sub-pillar forming part of the continuous, vertically-aligned, epitaxial nanopillar 16. The sub-pillars 32 can be stacked on one another, Nanopillars 16 formed from sub-pillars 32 can be used to replace any of the nanopillars 16 described herein. For example, sub-pillar-based nanopillars 16 can be coated; can be surrounded by a matrix phase 24, or both, as shown in FIG. 9. In addition, as shown in FIG. 10 each of the sub-pillars 32 can be coated with a sub-coating 34 and can be immersed by a matrix phase 24.

As will be understood the composition of the materials described herein can vary greatly depending on the particular application. The biaxially-textured surface 14 can be the surface of any biaxially textured substrate 12 including one or more layers. Examples of suitable materials for the substrate include, but are not limited to, a single crystal substrate; a biaxially textured substrate; and an untextured substrate having adhered thereon a biaxially-textured crystallographic surface, such as an ion-beam assisted deposition (IBAD) substrate.

The matrix phase 24, nanopillars 16, coatings 28 and core phase 30 can be any material useful in an article 10 having a substrate 12 with a biaxially textured surface 14, including, but not limited to, a superconducting material, a buffer material, a ferroelectric material, a multiferroic material, a magnetic material, a photovoltaic material, an electrical storage material, and a semiconductor material. Exemplary compositions for the matrix phase 24, nanopillars 16, coatings 28 and core phase 30 include, but are not limited to, metals, oxides, nitrides, borides, carbides and combinations thereof. Where the composition of the matrix phase 24, nanopillars 16, coatings 28 and/or core phase 30 is not amorphous, the compositions can have a variety of crystal structures, which independently include, but are not limited to, rock-salt, fluorite, perovskite, double-perovskite and pyrochlore. The nanopillars 16, coatings 28 and/or core phase 30 can be formed using any technique useful for applying thin films, whether epitaxial or not, including, but not limited to, laser ablation, sputtering, e-beam co-evaporation, chemical vapor deposition, metal-organic chemical vapor deposition, chemical solution deposition, liquid phase epitaxy, hybrid liquid phase epitaxy, chemical solution deposition methods, such as using metal-organic deposition (MOD) techniques, and the like. Of course, the composition and deposition technique of the matrix phase 24, nanopillars 16, coatings 28 and core phase 30, will depend on the particular application in which the article 10 is used.

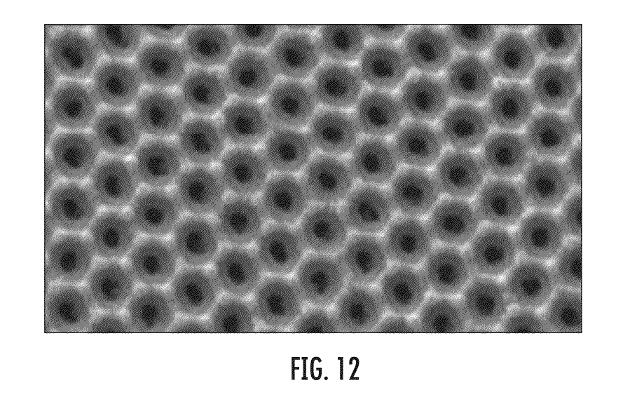

The plurality of nanopillars 16 can be arranged in a regular pattern. For example, it will be apparent that nanopillars 16 formed in the pores shown in FIG. 12 are arranged in a regular quadrilateral shape, e.g., a diamond shape. This results in an array of nanopillars 16 where each nanopillar 16 is equidistant to adjacent nanopillars 16. In particular, the arrays of nanopillars 16 described herein include rows or columns of nanopillars 16 where each nanopillar 16 in the row or column is equidistant from each adjacent nanopillar 16. The rows or columns in these arrays include at least 5 nanopillars, at least 10 nanopillars, at least 20 nanopillars, or at least 50 nanopillars where each nanopillar in the row or column is equidistance from each adjacent nanopillar. As used herein, the nanopillars are equidistant if the difference between the distance between two adjacent nanopillars is less than 15%, less than 10%, or less than 5%, or less than 1% different than the distance between other adjacent nanopillars in the row or column.

The articles described herein can be formed using a variety of different methods consistent with the descriptions provided herein. However, it is to be understood that the methods described herein are exemplary and that there may exist variations that would also produce the articles disclosed herein.

A method of fabricating an article 10 including a plurality of vertically-aligned, epitaxial nanopillars 16 is described. As shown in FIG. 7, the method can include providing a substrate 12 having a biaxially textured surface 14. The substrate 12 can include a layer having a biaxially textured surface. Exemplary techniques for producing a biaxially textured surfaces include RABiTS (Rolling-assisted biaxially textured substrates) and IBAD (Ion-beam assisted substrates) which enable reproducible fabrication of wide-area, long length, single-crystal-like and single-crystal substrates. See, for example, U.S. Pat. No. 7,087,113 by Goyal. Additional exemplary techniques for producing biaxially-textured substrates include, but are not limited to, inclined substrate deposition (ISD), ion-beam assisted deposition (IBAD) or single substrates by secondary recrystallization.

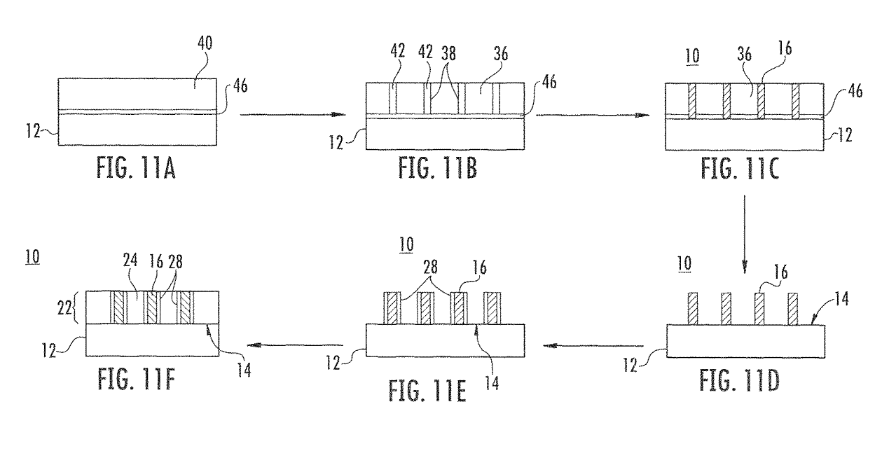

A template 36 defining a nanocatalyst pattern 38 can be formed on the biaxially textured surface 14 as shown in FIGS. 7A-7B and 11A-B. As shown in FIGS. 7A and 11A, the template 36 can be formed by depositing a template precursor layer 40 comprising a metal on the biaxially textured surface 14. The template precursor layer 40 can be anodized to form the template 36. As shown in FIGS. 7 & 11, an anodization catalyst layer 46 can be deposited on the biaxially textured surface 14 and the template precursor layer 40 can be deposited on the anodization catalyst layer 46. Alternately, the anodization catalyst layer 46 can be supported on the biaxially textured surface 14 and the template precursor layer 40 can be supported on the anodization catalyst layer 46. An anodization catalyst layer 46 can be present or absent depending on the desired embodiment. Exemplary materials for the template precursor layer 40 include metals, including, but not limited to, titanium, magnesium, zinc, niobium, tantalum and aluminum.

As shown in FIGS. 7B and 11B, the nanocatalyst pattern 38 can include pores 42 formed during the anodizing step, which can last until the pores 42 extend from a bottom surface 43 of the template 36 to a top surface 44 of the template 36. Generally, this requires complete anodization of the metal in the template precursor layer 40.

After producing the template, the plurality of vertically-aligned, epitaxial nanopillars 16 can be grown on the biaxially textured surface 14. In some instances, after formation of the template, the catalyst layer, anodized or unanodized portions of the template layer, or other debris may be covering the biaxially textured surface 14. In such instances, it may be necessary to remove the film, layer or debris prior to growing the vertically-aligned, epitaxial nanopillars 16. One approach for removing such films, layers or debris, including using an etchant. The nanopillars 16 can be nanotubes 20, as shown in FIG. 7C, or nanorods 18, as shown in FIG. 11C.

With respect to nanorods 18, the template 36 can be removed, as shown in FIG. 11D. In one example, the template 36 can be removed using an etchant that dissolves the template material 36, but not the substrate 12 or nanorods 18. The etching can continue until the exterior surface of the nanopillars 16 and the biaxial textured surface 14 are exposed. In instances where an anodization catalyst layer 46 is utilized, the catalyst layer 46 can also be removed at the time the template 36 is removed or in a separate step.

Following removal of the template 36, an optional coating 28 can be deposited on the plurality of vertically-aligned, epitaxial nanopillars 16, as shown in FIG. 11E. The coating 28 can be epitaxial or non-epitaxial. The coating 28 can be applied using nanofilm deposition techniques know in the art.

As shown in FIG. 11F, the matrix phase 24 can be deposited on the biaxially textured surface 14. The matrix phase 24 can be disposed between the plurality of vertically-aligned, epitaxial nanopillars 16. In some examples, the plurality of vertically-aligned, epitaxial nanopillars 16 can be immersed in the matrix phase 24 to form an article such as that shown in FIG. 4. Where the matrix phase 24 is epitaxial, the matrix phase can be grown or deposited around the nanopillars in two broadly defined ways:

(1) In-Situ Deposition: In this case, the film is deposited epitaxially on the biaxially textured surface 14 over, around and throughout the plurality of nanopillars 16 using an in-situ deposition technique including, but not limited to, laser ablation, sputtering, e-beam co-evaporation, chemical vapor deposition, metal-organic chemical vapor deposition, chemical solution deposition, liquid phase epitaxy, hybrid liquid phase epitaxy, and the like. The result is an epitaxial matrix phase 24 deposited on the biaxially textured surface 14 between the nanopillars 16.

(2) Ex-Situ Deposition: In this case, first a precursor film is deposited on the biaxially textured surface 14 over, around and throughout the plurality of nanopillars 16. This is followed by a heat-treatment or an annealing step at a temperature greater than 500° C. to form an epitaxial matrix phase 24, e.g., a superconductor matrix phase, within which the nanopillars 16 are embedded. Examples of techniques for this step include, but are not limited to, chemical solution deposition methods, such as using metal-organic deposition (MOD) techniques, particularly with fluorine-containing precursors or e-beam or thermal co-evaporation with fluorine-containing precursors.

With respect to nanotubes 20, once the nanotubes 20 are formed in the template 36 it is possible fill the core of the nanotubes 20 with a core phase 30. The core phase 30 can be epitaxial or non-epitaxial.

One option, which is shown in FIG. 7D, is to fill the nanotubes 20 with the core phase 30 prior to removal of the template 36. The template 36 then be removed and, optionally, a matrix phase 24 deposited around the nanotubes 20 as shown in FIGS. 7E and 7D.

A second option, which is shown in FIG. 7G, is to remove the template 36 to produce a plurality of vertically-aligned, epitaxial nanotubes 20 deposited on the biaxially-textured substrate 14. Optionally, the matrix phase 24 can be deposited on the biaxially-textured substrate 14. In this instance, the core phase 30 can be co-deposited with the matrix phase 24 and the core phase 30 and matrix phase 24 will have the same composition.

A method is also disclosed for producing nanopillars 16 that include a plurality of sub-pillars 32, as shown in FIGS. 8-10. The sub-pillars 32 can be nanorods 18, nanotubes 20, or both.

Sub-pillars 32 can be formed using iterative variations of the methods shown in FIGS. 7 and 11. For example, the steps of FIGS. 11A-C can be performed to produce a first layer of sub-pillars 32. A second layer of sub-pillars can then be formed by introducing and anodizing another template precursor and depositing vertically-aligned, epitaxial sub-pillars 32 in the pores 42 of the second template. This process can be repeated to produce the desired number of subpillars. Following formation of the sub-pillars, coatings 28 and matrix phases 24 can be added depending on the desired application.

An alternate approach for forming sub-pillars 32 is to repeat the entire process shown in FIG. 7 or 11. Such an approach allows formation of sub-coatings 34 to match the composition of each individual sub-pillar 32 and/or formation of different matrix phases 24 to match the composition of each individual sub-pillar 32.

The present invention has broad applicability for energy conversion as well as in areas of nanoelectronics such as ultra-high density magnetic storage and in nanostructured battery electrodes. Epitaxial nanorod arrays of materials with scintillation properties may be used for fabrication of advanced gamma-ray detectors. Thus, potential applications include, but are not limited to, a range of sensors and detectors, superconductors, ferroelectrics, semiconductors, micro-circuitry, and other nanoelectronics-based devices.

Applications for the articles and methods described herein include dye-sensitized cells (DSC's) and hybrid organic-inorganic cells, which are widely considered as promising candidates for inexpensive, large-scale solar energy conversion. Prior art DSC's consist of a thick nanoparticle film that provides a large surface area for adsorption of light. Device efficiencies for such DSC's are limited by the trap-limited limited diffusion for electron transport, which is a slow process. It is believed that use of a nanopillar morphology would increase efficiency by accelerating electron transport and preventing recombination of electron-hole pairs.

The use of vertically-oriented, single crystal nanopillars of TiO₂, SnO or ZnO will result in significant enhancement in electron transport. Coating the aligned nanorods with an oxide such as MgO can reduce carrier recombination because the coating may serve as an additional energy barrier, as a tunneling barrier and/or a passivate recombination center. In similar prior art materials, the nanorods are not perfectly aligned, consist of polycrystalline percolation networks, or both.

The advantages of a perfectly aligned, epitaxial, single-crystal-like, nanopillar array is even more compelling for other types of excitonic photocells such as inorganic-organic hybrid devices. For example, longitudinal magnetic recording, a multi-billion dollar data storage industry is facing a turning point—while great strides have been made by reducing critical physical dimensions and store more information in smaller areas, progress in areal density of storage has slowed due to the fundamental superparamagnetic limit due to thermal instabilities in the recording media.

It is believed that patterned media and perpendicular recording media may enable recording densities substantially beyond the 1 Tbit/in² threshold. An ideal microstructure envisioned in the field is a vertically aligned, 3-dimensional nanodot array of magnetic materials. These can also be viewed as vertically aligned nanorods, with each nanorod really being a composite rod, alternating in its composition along its length, for example each rod being alternating stacks of Co and Pd. The methods described herein are fully capable of producing articles according to FIGS. 8-10, which can deliver the necessary nanostructure for such high density storage.

The epitaxial layers described herein, e.g., nanopillars, matrix phase, coating and core phase, can be deposited by a range of deposition techniques including e-beam evaporation, sputtering, chemical and physical vapor deposition techniques, pulsed laser ablation, chemical solution processing, and electrodeposition techniques (for example, U.S. Pat. No. 6,670,308 by Goyal).

Exemplary templates can be formed using a single crystal aluminum sheet (i.e., template precursor), followed by anodic oxidation to form a self-organized nanopore array in the resulting anodized aluminum oxide (AAO) layer (i.e., template). In a particular example, the template can be formed on the biaxially textured surface by depositing a layer of aluminum (Al) on the cap or top buffer layer of a single crystal-like substrate (e.g., a fully buffered RABiTS substrate with three epitaxial oxide buffers), followed by complete anodic oxidation of the aluminum layer. If the aluminum layer is non-epitaxial, the structure of the AAO template is shown in FIG. 12. In case the aluminum is deposited epitaxially on the top buffer layer of the substrate, then it will have a [100] orientation.

Anodic oxidation of an epitaxial Al layer may result in a pore structure which is different from that shown in FIG. 12. Regardless, anodic oxidation is performed until the surface of the cap or top buffer layer of the large-area single crystal substrate is visible through the nanopore structure. The surface of the cap layer inside the nanopores is then examined and modified by chemical cleaning or plasma cleaning if necessary, to provide an appropriate surface for epitaxial growth of the plurality of nanopillars. This is followed by epitaxial deposition of the nanorods array using an appropriate technique, including, but not limited to, e-beam deposition, sputtering, pulsed laser deposition and chemical solution deposition.

Once the epitaxial nanorod array has been deposited, the Al₂O₃ template can be chemically etched away if needed and, if needed, a matrix phase deposited between the epitaxial, single-crystal-like nanopillar array. For the ultra-high density recording media application, nanopillars comprising interconnected sub-pillars of different materials such as Co and Pd, will be epitaxially deposited successively using either physical vapor deposition or electrodeposition.

Moreover, it is contemplated that the present invention can be broadened, for example, by using an alternative to the AAO-type template to produce a nanocatalyst pattern. Laser interference lithography can be used to quickly produce a template pattern in nanoscale and in large areas.

Moreover, it is contemplated that growth of periodic nanostructures in two directions—vertical nanopillars and transverse nanopillars—can be achieved by supplying the catalyst for growth during deposition. For example, simultaneously depositing an oxide material with a metal catalyst such as MgO Ni growth by PLD. FIG. 13 is an image of MgO+Ni nanorods grown on a MgO single crystal. Growth of nanorods is observed vertically and horizontally due to the standard vapor-liquid-solid (VLS) growth mechanism and the MgO nanorods are epitaxial. Either of these techniques—laser interference lithography or VLS—can also be applied to existing vertically-oriented nanopillars after the template has been removed, for example to an article of FIG. 7E, 7G, 11D or 11E. This can be extended to the present invention and growth can be on large area, textured substrates.

While there has been shown and described what are at present considered to be examples of the invention, it will be obvious to those skilled in the art that various changes and modifications can be prepared therein without departing from the scope of the inventions defined by the appended claims.

We claim:

1. An article comprising:
a substrate having a biaxially textured surface, and
a plurality of vertically-aligned, epitaxial nanopillars supported by said biaxially textured surface substrate.

2. The article according to claim 1, wherein said plurality of vertically-aligned, epitaxial nanopillars comprise nanopillars selected from the group consisting of nanorods, nanotubes, and combinations thereof.

3. The article according to claim 1, further comprising a matrix phase deposited on said biaxially textured surface, wherein said matrix phase is disposed between said plurality of vertically-aligned, epitaxial nanopillars.

4. The article according to claim 3, said article comprising an electronically active layer comprising said matrix phase disposed between said plurality of vertically-aligned, epitaxial nanopillars.

5. The article according to claim 4, wherein said electronically active layer is selected from the group consisting of a superconducting material, a ferroelectric material, a multiferroic material, a magnetic material, a photovoltaic material, a electrical storage material, and a semiconductor material.

6. The article according to claim 3, wherein said matrix phase is an epitaxial layer.

7. The article according to claim 1, wherein a diameter of said vertically-aligned, epitaxial nanopillars ranges from 5-100 nm.

8. The article according to claim 1, wherein said vertically-aligned, epitaxial nanopillars comprise at least two epitaxial sub-pillars having different compositions along a length of each of said vertically-aligned, epitaxial nanopillars.

9. The article according to claim 1, further comprising:
a coating deposited on said plurality of vertically-aligned, epitaxial nanopillars.

10. The article according to claim 9, further comprising an matrix phase deposited on said biaxially textured substrate, wherein said matrix phase is disposed between said plurality of vertically-aligned, epitaxial nanopillars.

11. The article according to claim 10, said article comprising an electronically active layer comprising said matrix phase disposed between said plurality of vertically-aligned, epitaxial nanopillars, wherein said electronically active layer is selected from the group consisting of a superconducting material, a ferroelectric material, a multiferroic material, a magnetic material, a paramagnetic material, a photovoltaic material, an electrical storage material, and a semiconductor material.

12. The article according to claim 10, wherein said matrix phase is an epitaxial layer.

13. The article according to claim herein said coating is an epitaxial layer.

14. The article according to claim 9, wherein said vertically-aligned, epitaxial nanopillars are single crystal nanopillars.

15. The article according to claim 9, wherein said vertically-aligned, epitaxial nanopillars comprise at least two epitaxial sub-pillars having different compositions along a length of each of said vertically-aligned, epitaxial nanopillar.

16. A method of fabricating a device comprising a plurality of vertically-aligned, epitaxial nanopillars comprising:
a. providing a substrate having a biaxially textured surface;
b. forming a template on said biaxially textured surface, said template defining a nanocatalyst pattern; and
c. growing an epitaxial layer on said biaxially textured surface, said epitaxial layer comprising a plurality of vertically-aligned, epitaxial nanopillars deposited in said nanocatalyst pattern.

17. The method according to claim 16, wherein said forming step comprises:
depositing an anodization catalyst layer supported on the biaxially textured surface;
depositing a template precursor layer comprising a metal supported on said anodization catalyst layer; and
anodizing said metal template precursor layer to form said template, wherein said nanocatalyst pattern comprises pores formed during said anodizing step, said pores extending from a bottom surface of said template to a top surface of said template.

18. The method according to claim 17, further comprising:
removing said template to expose said plurality of vertically-aligned, epitaxial nanopillars and the biaxially textured surface between said plurality of vertically-aligned, epitaxial nanopillars.

19. The method according to claim 18, further comprising:
depositing a matrix phase on said biaxially textured substrate, wherein said matrix phase is disposed between said plurality of vertically-aligned, epitaxial nanopillars.

20. The method according to claim 18, further comprising:
depositing an epitaxial coating on said plurality of vertically-aligned, epitaxial nanopillars; and
depositing a matrix phase on said biaxially textured substrate, wherein said matrix phase is disposed between said plurality of vertically-aligned, epitaxial nanopillars.
